(19) United States
(12) Patent Application Publication
(10) Pub. No.: US 2008/0073721 A1
(43) Pub. Date: Mar. 27, 2008

(54) SEMICONDUCTOR INTEGRATED CIRCUIT DEVICE

(75) Inventor: Chikashi FUCHIGAMI, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/781,326

(22) Filed: Jul. 23, 2007

(30) Foreign Application Priority Data
Sep. 21, 2006 (JP) 2006-255424

(51) Int. Cl. H01L 23/62

(52) U.S. Cl. 257/355; 257/E27.016

(57) ABSTRACT

A semiconductor integrated circuit device includes at least one MOS transistor that is formed in a main region of the circuit device. The main region has one conductivity type. The semiconductor integrated circuit device also includes a guard ring region formed surrounding the MOS transistor and in contact with the main region. The guard ring has the same conductivity type as the main region. The semiconductor integrated circuit device further includes an anode region formed facing the guard ring region and in contact with the main region. The anode region has the opposite conductivity type to the main region. The semiconductor integrated circuit device also includes a cathode region having at least a portion of the guard ring region. The anode region, the main region, and the cathode region form a diode.

### BACKGROUND OF THE INVENTION

1. Field of the Invention

The present invention relates to a semiconductor integrated circuit device provided with an electrostatic discharge (ESD) protection circuit to prevent ESD damage.

2. Description of the Related Art

Semiconductor integrated circuit devices usually require the insertion of ESD protection circuits as measures to prevent ESD damage. For example, transistors or diodes, that are separate from the output transistors required for the operation of the device, are inserted into the semiconductor integrated device as ESD protection circuits.

When a transistor is used as an ESD protection circuit, the size of the circuit must be large so that the protection transistor itself is not damaged. This causes the ESD protection circuit to occupy more area than the output transistor. When a diode is used as the ESD protection circuit, the diode has a different shape from the output transistor. This requires the diode to be fabricated in a region separate from the output transistor. While the size of the circuit is smaller than a circuit configuration which uses a transistor as the ESD protection circuit, the ESD protection circuit made from the diode still occupies a relatively large surface area of the semiconductor integrated device.

FIG. 1 of the accompanying drawings is a drawing (FIG. 7) of Japanese Patent Application Kokai (Laid open) No. 2000-40751. The device of JP 2000-40751 has an n-well guard ring 6 which is formed along a periphery of an NMOS field effect transistor A. The n-well guard ring 6 and an n-well 3 of a PMOS field effect transistor B are strapped together by a metal 5. Reference numeral 4 designates a metal contact. This structure can reduce the layout area by forming a PNPN path.

Once this type of thyristor structure formed by such a PNPN path conducts a latch-up current, this current does not stop. This prevents the semiconductor integrated circuit device from operating normally, and results in damage of the integrated circuit device. The use of this PNPN path, which is formed as a result of forming the output transistor and the guard ring region (i.e., which is formed parasitically), does not secure the protection performances required to a protection diode (e.g., current-carrying capacity).

### SUMMARY OF THE INVENTION

One object of the present invention is to provide a semiconductor integrated circuit provided with an ESD protection circuit that reduces the area occupied by the ESD protection circuit while securing appropriate protection performance of the ESD protection circuit.

According to one aspect of the present invention, there is provided a semiconductor integrated circuit device that includes at least one MOS transistor formed in a main region of the circuit device. The main region has a predetermined conductivity type. The semiconductor integrated circuit device also includes a guard ring region formed surrounding the MOS transistor and in contact with the main region. The guard ring region has the same conductivity type as the main region. The semiconductor integrated circuit device further includes an anode region formed facing the guard ring region and in contact with the main region. The anode region has the opposite conductivity type to the main region. The semiconductor integrated circuit device also includes a cathode region. The cathode region is established having at least a portion of the guard ring region. The anode region, the main region, and the cathode region form in combination a diode. This diode is a protection diode for ESD damage.

The protection diode is formed by providing the anode region that faces the guard ring region on the semiconductor substrate and by using the guard ring region as the cathode region. This makes it possible to not only reduce the area that is occupied by the ESD protection diode, but also to secure an appropriate protection performance.

### BRIEF DESCRIPTION OF THE DRAWINGS

FIG. 1 illustrates the layout of a conventional ESD protection circuit;

FIG. 2 is a plan view of a semiconductor integrated circuit device according to a first embodiment of the present invention;

FIG. 3 is a cross sectional view taken along the line III-III in FIG. 2;

FIG. 4 is a circuit diagram showing an equivalent circuit of the structure shown in FIG. 2 and FIG. 3; and

FIG. 5 is a plan view of a semiconductor integrated circuit device according to a second embodiment according to the present invention.

### DETAILED DESCRIPTION OF THE INVENTION

Embodiments of the present invention will now be described in detail with reference to the accompanying drawings.

### First Embodiment

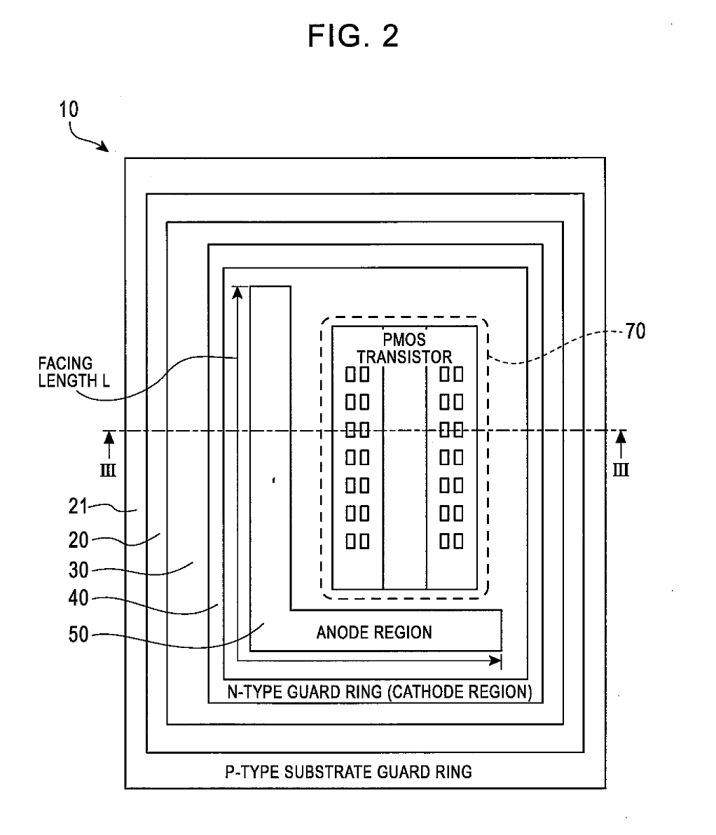

Referring to FIG. 2, the first embodiment of the semiconductor integrated circuit device 10 according to the present invention will be described. The semiconductor integrated circuit device 10 constitutes a so-called LSI (a large-scale integrated) circuit. A large number of semiconductor elements, such as PMOS transistors and NMOS transistors for achieving a variety of functions, are formed on a P-type substrate 20. In particular, a PMOS transistor 70 is formed, as an output transistor that is shown in the drawing, on the P-type substrate 20, with an n-well 30 interposed therebetween. The PMOS transistor 70 is assumed to be electrically connected to the outside through an output terminal, requiring ESD protection countermeasures.

The n-well 30 is the main region of the circuit device 10 and has an N type conductivity. In this embodiment, one conductivity type (first conductivity type) is an N type and the other (or second) conductivity type is a P type.

An N-type guard ring 40 is formed on the n-well 30 so as to surround the PMOS transistor 70. The guard ring region is normally an isolation region provided in order to prevent the latch up that can occur in a CMOS device that has a PMOS transistor and an NMOS transistor. A P-type substrate guard ring 21 is formed on the P-type substrate 20 so as to surround the N-type guard ring 40. An anode region 50, which is one of the characterizing elements of the present invention, is formed between the PMOS transistor 70 and the N-type guard ring 40. The shape of the anode region 50 is designed to face the N-type guard ring 40. The anode region 50 may be formed in a strip shape so as to face one side of a rectangular N-type guard ring 40. Alternatively, the anode region 50 may be formed in an L shape so as to face two sides of the N-type guard ring 40 as shown in FIG. 2, or may be formed in a rectangular shape so as to encompass the PMOS transistor 70.

A protection diode for protecting the semiconductor integrated circuit device 10 from ESD damage is formed by a cathode region made from at least a portion of the N-type guard ring 40, the anode region 50, and the n-well 30. The facing length L is defined as the length over which the anode region 50 and the N-type guard ring 40 face each other. The facing length L must be determined appropriately in order to secure the protection properties, such as current-carrying capacity, required for the protection diode.

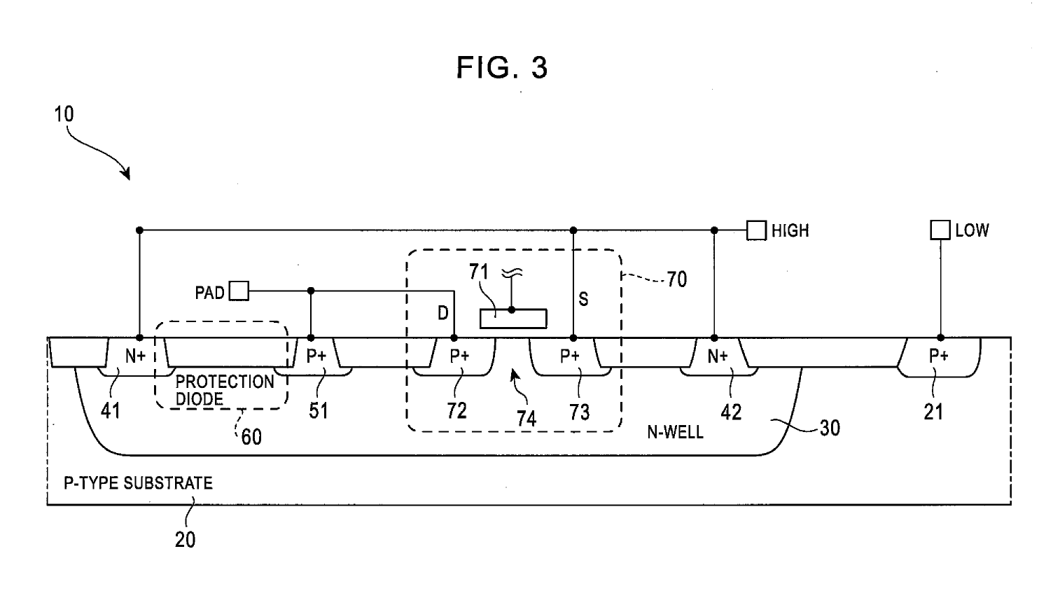

FIG. 3 shows a cross sectional view taken along the line III-III in FIG. 2. The n-well 30 is formed on top of the P-type substrate 20. The PMOS transistor 70 is formed with a portion of the n-well 30 which serves as a drift region 74. The PMOS transistor 70 includes a P-type high concentration region 72 and another P-type high concentration region 73 that are exposed on a substrate. The PMOS transistor 70 also includes a polysilicon region 71. In the manufacturing process, the n-well 30 is exposed between the P-type high concentration regions 72 and 73. This exposed part is adjacent to the polysilicon region 71 with an insulating layer (not shown) interposed therebetween. The polysilicon region 71 serves as a gate region of a field effect transistor, and is connected to another signal path within the semiconductor integrated circuit device 10 through an appropriate contact member. The P-type high concentration region 72 serves as a drain region of the field effect transistor, and is connected to an external output terminal PAD through an appropriate contact member. The P-type high concentration region 73 serves as a source region of the field effect transistor, and is connected to the power supply High through an appropriate contact member.

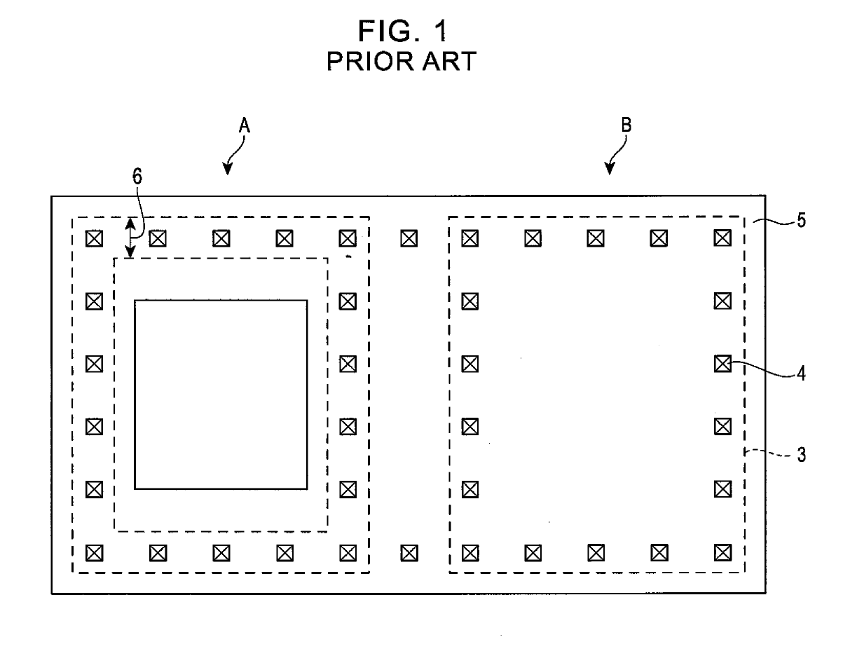

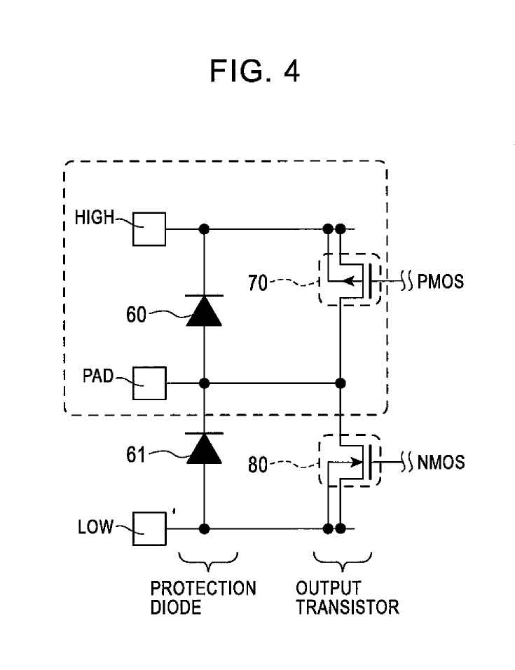

An N-type high concentration region 41 and another N-type high concentration region 42 are formed on both sides of the n-well 30 as shown in FIG. 4. The N-type high concentration region 41 and N-type high concentration region 42 form a portion of the N-type guard ring 40 shown in FIG. 1. The N-type high concentration regions 41 and 42 are connected to the power supply High through an appropriate contact member.

The P-type substrate guard ring 21 is formed on top of the P-type substrate 20, in a shape as shown in FIG. 1, and serves as a P-type high concentration region. The P-type substrate guard ring 21 is connected to a second power supply Low through an appropriate contact member.

A P-type high concentration region 51 is provided between the PMOS transistor 70 and the N-type high concentration region 41 that forms the N-type guard ring, and forms a portion of the anode region 50 (FIG. 1). The P-type high concentration region 51 is connected to the external output terminal PAD through an appropriate contact member. The P-type high concentration region 51 and the N-type high concentration region 41 establish, in effect, a PN junction through the n-well 30, thereby forming a protection diode 60.

Referring to FIG. 4, an equivalent circuit of the structure shown in FIGS. 2 and 3 will be described. The gate of the PMOS transistor 70 is connected to another signal path (not shown) within the semiconductor integrated circuit device 10, the source thereof is connected to the power supply High, and the drain thereof is connected to the output terminal PAD. Similarly, the gate of the NMOS transistor 80 is connected to another signal path (not shown) within the semiconductor integrated circuit device 10, the source thereof is connected to the power supply Low, and the drain thereof is connected to the output terminal PAD. An output driver of the semiconductor integrated circuit device 10 has the CMOS structure that is formed from the PMOS transistor 70 and the NMOS transistor 80.

In the equivalent circuitry, a protection diode 60 is connected between the source and drain of the PMOS transistor 70, and a protection diode 61 is connected between the source and drain of the NMOS transistor 80. The protection diodes 60 and 61 have a forward threshold voltage Vf in the same manner as in a normal PN connection diode. Therefore, even if a surge voltage of an ESD high voltage waveform is applied to the output terminal PAD of the semiconductor integrated circuit device 10, the surge voltage escapes to the power supply line through the protection diode 60 (or 61) when the surge voltage exceeds the threshold value Vf (e.g., 0.6 volts) of the protection diode 60 (or 61). Accordingly, electrostatic discharge damage can be prevented without applying a high voltage to the PMOS transistor 70 and NMOS transistor 80.

In the first embodiment as described above, the guard ring region of the PMOS transistor is also used as the cathode region of the protection diode that is the ESD protection circuit, and the PMOS transistor is surrounded by the anode region of the protection diode, thereby achieving an ESD protection circuit having adequate capability in a small area. Moreover, the required ESD protection performance can be secured through the appropriate selection of the facing length L. The facing length L is the length over which the anode region and the guard ring region face each other.

### Second Embodiment

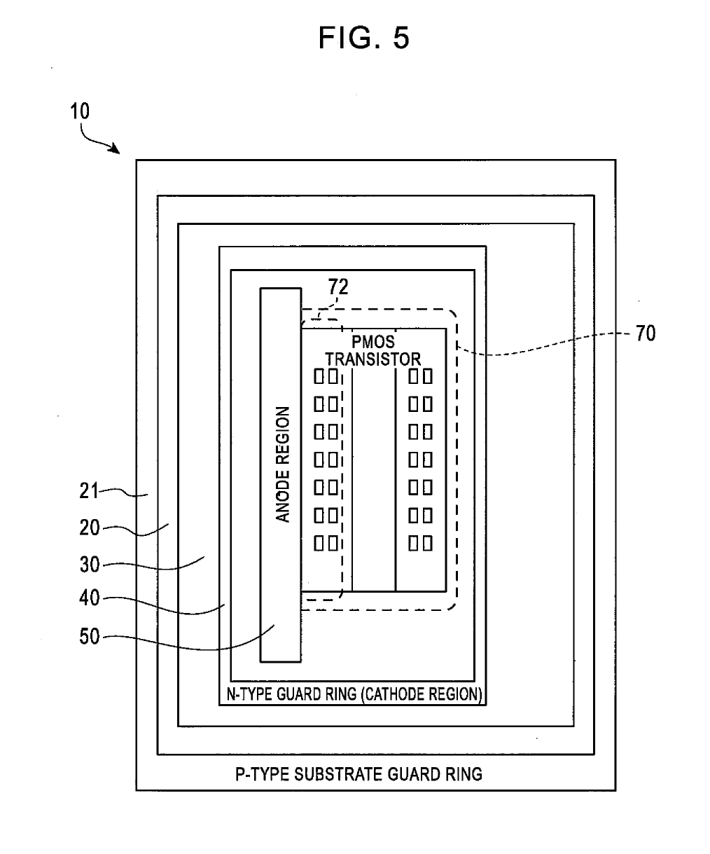

Referring to FIG. 5, a second embodiment of the semiconductor integrated circuit device 10 according to the present invention will be described. Similar reference numerals and symbols are used in the first and second embodiments to designate similar elements. In the semiconductor integrated circuit device 10, a PMOS transistor 70 is formed, as an output transistor, on a P-type substrate 20 with an n-well 30 interposed therebetween, in the same manner as in the first embodiment. The PMOS transistor 70 is assumed to be electrically connected to the outside through an output terminal. This requires ESD protection countermeasures.

An N-type guard ring 40 is formed on the n-well 30 so as to surround the PMOS transistor 70. A P-type substrate guard ring 21 is formed on the P-type substrate 20 so as to surround the N-type guard ring 40. An anode region 50, which is one of the most important elements of the present invention, is formed between the PMOS transistor 70 and the N-type guard ring 40. The anode region 50 is in contact with the drain region (P-type high concentration region) 72 of the PMOS transistor 70. The shape of the anode region 50 is designed to have an appropriate facing length between the N-type guard ring 40 and the anode region 50.

In the second embodiment, the anode region of the protection diode is in contact with the drain region that is connected to the output terminal of the output transistor. Thus, the ESD protection circuit with a smaller area can be achieved.

In the above described embodiments, at least a portion of the guard ring region of the output transistor is also used as the cathode region of a protection diode, and an anode region is provided so that an appropriate facing length over which different conductivity types (i.e., the P-type and N-type) face each other is secured between the anode region and the guard ring region.

The performance of the protection diode is determined by the magnitude of the facing length of the PN junction, and it is necessary to have the facing length as long as possible so as to secure the current-carrying capacity. Moreover, in order to prevent the protection diode itself from malfunctioning due to noise, more particularly, in order to have an adequate performance in terms of electron supply capability and the like, a guard ring and a substrate contact are required around the protection diode. Thus, there is a limit to reducing the area. The present invention can reduce the area without a loss in the protection performance that is required in the protection diode because the guard ring region is used as the cathode region.

### Modifications

Although the output transistor is a PMOS transistor in the above described embodiments, the output transistor can be a combination of an NMOS transistor and a protection diode. In this case, the conductivity types (i.e., P-type and N-type) of the MOS transistor and the protection diode are switched. If the NMOS transistor is provided on a P-type substrate, the n-well is not required. In other words, the P-type substrate forms the main region of the semiconductor integrated circuit device, and has the P-type that is the first conductivity type.

If a plurality of output transistors are disposed with narrow gaps therebetween such as in driver terminals, the area can be further reduced by disposing diode cathodes or anodes between the output transistors and sharing the diode cathodes or anodes between the output transistors.

The semiconductor integrated circuit device according to the present invention is not limited to a semiconductor integrated circuit device that is provided with an ESD protection circuit for protecting an output transistor, but can be a semiconductor integrated circuit device including a circuit that requires the provision of an ESD protection circuit due to the possibility of exposure to an external electric field such as in an input terminal.

This application is based on Japanese Patent Application No. 2006-255424 filed on Sep. 21, 2006 and the entire disclosure thereof is incorporated herein by reference.

What is claimed is:

1. A semiconductor integrated circuit device comprising:
at least one MOS transistor that is formed in a main region having one conductivity type;
a guard ring region formed surrounding the MOS transistor and in contact with the main region, and having the one conductivity type;
an anode region formed facing the guard ring region and in contact with the main region, and having another conductivity type; and
a cathode region having at least a portion of the guard ring region, wherein the anode region, the main region, and the cathode region form a diode.

2. The semiconductor integrated circuit device according to claim 1, wherein the anode region is formed between the MOS transistor and the guard ring region.

3. The semiconductor integrated circuit device according to claim 1, wherein the anode region is electrically connected to a drain region of the MOS transistor.

4. The semiconductor integrated circuit device according to claim 1, wherein the anode region is formed in contact with a drain region of the MOS transistor.

5. The semiconductor integrated circuit device according to claim 1, wherein the main region is an n-well of a semiconductor substrate.

6. The semiconductor integrated circuit device according to claim 1, wherein the anode region has an elongated strip shape.

7. The semiconductor integrated circuit device according to claim 1, wherein the anode region has a rectangular shape.

8. The semiconductor integrated circuit device according to claim 1, wherein the anode region has an L shape.

9. The semiconductor integrated circuit device according to claim 1, wherein the diode is an electrostatic discharge protection diode.

10. The semiconductor integrated circuit device according to claim 1 further comprising a second guard ring region around the diode.

11. The semiconductor integrated circuit device according to claim 1, wherein the main region is a part of a P-type semiconductor substrate.
